(19) United States
(12) Patent Application Publication
(10) Pub. No.: US 2026/0304763 A1
(43) Pub. Date: Oct. 1, 2026

(54) MEMORY DEVICE AND MANUFACTURING METHOD THEREOF

(71) Applicant: MACRONIX INTERNATIONAL CO., LTD., HSINCHU (TW)

(72) Inventors: Yu-Tang LIN, Taipei City (TW); Guan-Ru LEE, Hsinchu City (TW); Chia-Jung CHIU, Zhubei City (TW)

(21) Appl. No.: 19/064,844

(22) Filed: Feb. 27, 2025

(51) Int. Cl. H10B 43/27; G11C 5/06; H10B 43/10; H10B 43/35

(52) U.S. Cl. CPC H10B 43/27; G11C 5/063; H10B 43/10; H10B 43/35

(57) ABSTRACT

A memory device includes a substrate, a buffer layer, a stacked structure, and a channel pillar. The buffer layer is on the substrate. The stacked structure is located on the buffer layer, in which the stacked structure includes a plurality of gate layers and a plurality of first insulating layers stacked alternately. The channel pillar extends through the stacked structure and is embedded in the buffer layer, in which the channel pillar includes a charge storage structure and a channel layer, the charge storage structure is located between the plurality of gate layers and the channel pillar.

### BACKGROUND

### Field of Disclosure

The present disclosure relates to a memory device and a manufacturing method thereof.

### Description of Related Art

Since a non-volatile memory has the advantage that stored data does not disappear at power-off, it becomes a widely used memory for a personal computer or other electronics equipment. Currently, the three-dimensional (3D) memory commonly used in the industry includes a NOR memory and a NAND memory. In addition, another type of 3D memory is an AND memory, which may be applied to a multi-dimensional memory array with high integration and high area utilization, and has an advantage of a fast operation speed. Therefore, the development of a 3D memory device has gradually become the current trend. However, there are still many challenges associated with the 3D memory device.

### SUMMARY

A memory device according to an embodiment of the present disclosure includes a substrate, a buffer layer, a stacked structure, and a channel pillar. The buffer layer is on the substrate. The stacked structure is located on the buffer layer, in which the stacked structure includes a plurality of gate layers and a plurality of first insulating layers stacked alternately. The channel pillar extends through the stacked structure and is embedded in the buffer layer, in which the channel pillar includes a charge storage structure and a channel layer, the charge storage structure is located between the plurality of gate layers and the channel pillar.

A manufacturing method of a memory device according to an embodiment of the present disclosure includes forming a conductive layer on a buffer layer on a substrate, forming a stacked structure on the conductive layer, in which the stacked structure includes a plurality of intermediate layers and a plurality of first insulating layers stacked alternately, forming a channel trench extending through the stacked structure and the conductive layer into the buffer layer, forming a channel pillar in the channel trench, forming a slit trench extending through the stacked structure and the conductive layer, replacing the conductive layer and a portion of the channel pillar by a second insulating layer, replacing the plurality of intermediate layers by a plurality of gate layers; and forming a slit in the slit trench..

### BRIEF DESCRIPTION OF THE DRAWINGS

FIG. 1A shows a circuit diagram of a 3D AND flash memory array according to some embodiments.

FIG. 1B shows a partial 3D view of a portion of the memory array in FIG. 1A.

FIG. 1C and FIG. 1D show cross-sectional views along the line I-I′ of FIG. 1B.

FIG. 1E shows a top view of the line II-II′ OF FIG. 1B, FIG. 1C and FIG. 1D.

FIG. 2 to FIG. 14 are cross-sectional views of forming a 3D AND flash memory device in some embodiments of the present disclosure.

### DETAILED DESCRIPTION

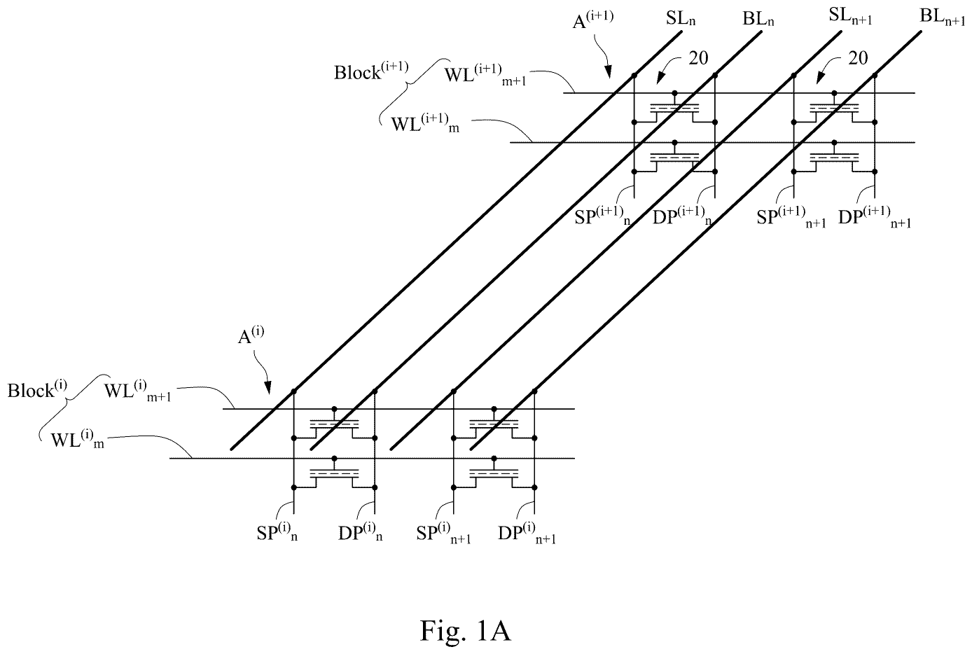

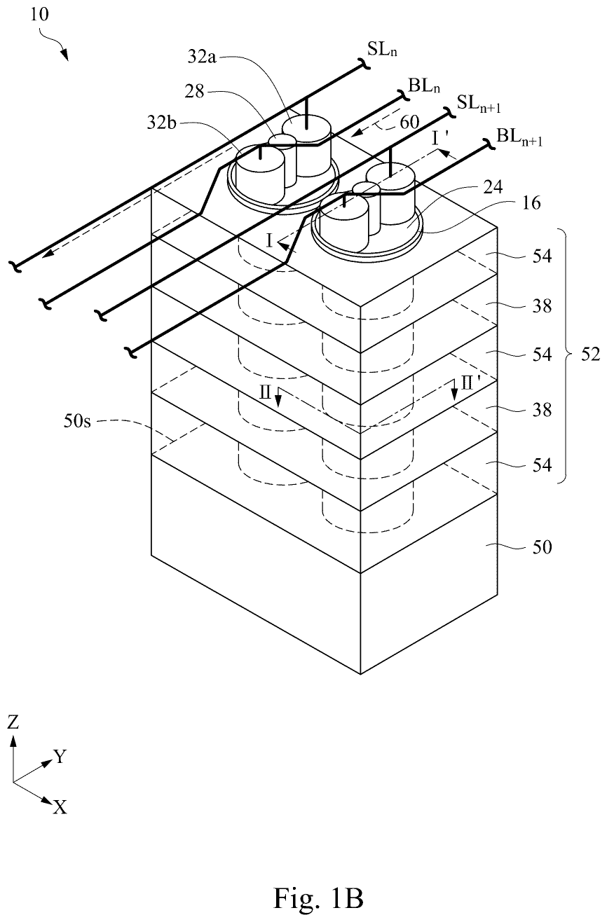

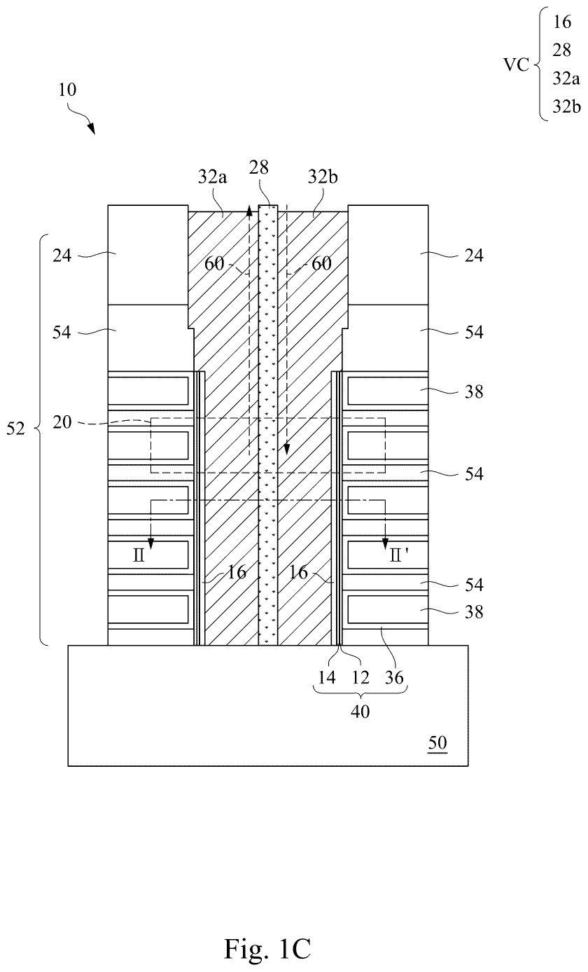

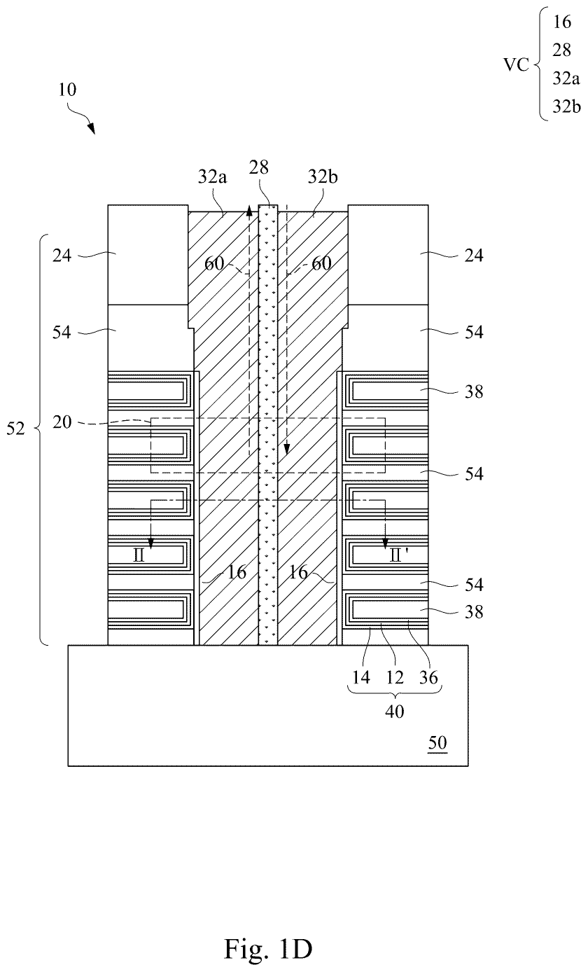

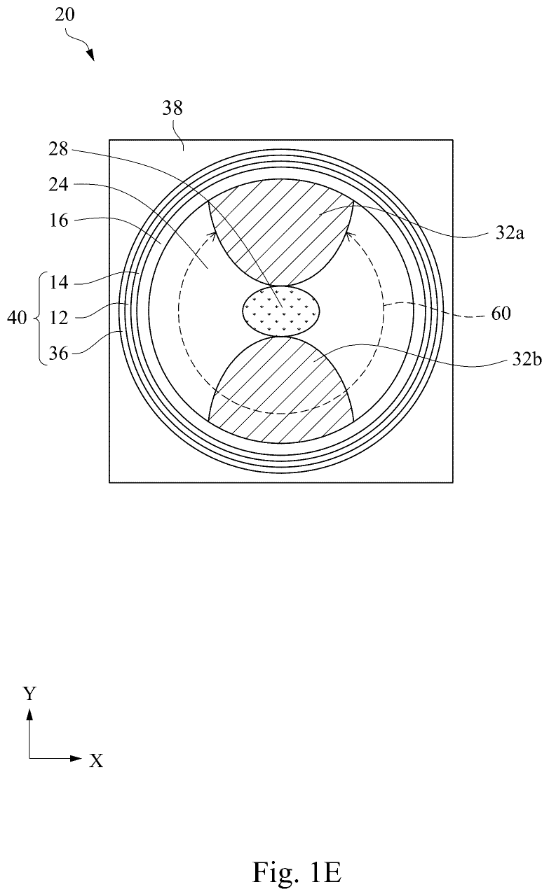

FIG. 1A shows a circuit diagram of a 3D AND flash memory array according to some embodiments. FIG. 1B shows a partial 3D view of a portion of the memory array in FIG. 1A. FIG. 1C and FIG. 1D show cross-sectional views along the line I-I′ of FIG. 1B. FIG. 1E shows a top view of the line II-II′ of FIG. 1B, FIG. 1C and FIG. 1D.

FIG. 1A is a schematic view of two blocks BLOCK⁽ⁱ⁾ and BLOCK⁽ⁱ⁺¹⁾ of a vertical AND memory array 10 arranged in rows and columns. The block BLOCK⁽ⁱ⁾ includes a memory array A⁽ⁱ⁾. A row (e.g., an (m+1)th row) of the memory array A⁽ⁱ⁾ is a set of AND memory cells 20 having a common word line (e.g., WL⁽ⁱ⁾ₘ₊₁). The AND memory cells 20 of the memory array A⁽ⁱ⁾ in each row (e.g., the (m+1)th row) correspond to a common word line (e.g., WL⁽ⁱ⁾ₘ₊₁) and are coupled to different source pillars (e.g., SP⁽ⁱ⁾ₙ and SP⁽ⁱ⁾ₙ₊₁) and drain pillars (e.g., DP⁽ⁱ⁾ₙ and DP⁽ⁱ⁾ₙ₊₁), so that the AND memory cells 20 are logically arranged in a row along the common word line (e.g., WL⁽ⁱ⁾ₘ₊₁).

A column (e.g., an nth column) of the memory array A⁽ⁱ⁾ is a set of AND memory cells 20 having a common source pillar (e.g., SP⁽ⁱ⁾ₙ) and a common drain pillar (e.g., DP⁽ⁱ⁾ₙ). The AND memory cells 20 of the memory array A⁽ⁱ⁾ in each column (e.g., the nth column) correspond to different word lines (e.g., WL⁽ⁱ⁾m+1 and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells 20 of the memory array A⁽ⁱ⁾ are logically arranged in a column along the common source pillar (e.g., SP⁽ⁱ⁾ₙ) and the common drain pillar (e.g., DP⁽ⁱ⁾ₙ). In the physical layout, according to the fabrication method as applied, the columns or rows may be twisted and arranged in a honeycomb pattern or other patterns for high density or other reasons.

In FIG. 1A, in the block BLOCK⁽ⁱ⁾, the AND memory cells 20 in the nth column of the memory array A⁽ⁱ⁾ share a common source pillar (e.g., SP⁽ⁱ⁾ₙ) and a common drain pillar (e.g., DP⁽ⁱ⁾ₙ). The AND memory cells 20 in an (n+1)th column share a common source pillar (e.g., SP⁽ⁱ⁾ₙ₊₁) and a common drain pillar (e.g., DP⁽ⁱ⁾ₙ₊₁).

The common source pillar (e.g., SP⁽ⁱ⁾ₙ) is coupled to a common source line (e.g., SLₙ) and the common drain pillar (e.g., DP⁽ⁱ⁾ₙ) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array A⁽ⁱ⁺¹⁾, which is similar to the memory array A⁽ⁱ⁾ in the block BLOCK⁽ⁱ⁾. A row (e.g., an (m+1)th row) of the memory array A⁽ⁱ⁺¹⁾ is a set of AND memory cells 20 having a common word line (e.g., WL⁽ⁱ⁺¹⁾ₘ₊₁). The AND memory cells 20 of the memory array A⁽ⁱ⁺¹⁾ in each row (e.g., the (m+1)th row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ and DP⁽ⁱ⁺¹⁾ₙ₊₁). A column (e.g., an nth column) of the memory array A⁽ⁱ⁺¹⁾ is a set of AND memory cells 20 having a common source pillar (e.g., SP⁽ⁱ⁺¹⁾ₙ) and a common drain pillar (e.g., DP⁽ⁱ⁺¹⁾ₙ). The AND memory cells 20 of the memory array A⁽ⁱ⁺¹⁾in each column (e.g., the nth column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells 20 of the memory array A⁽ⁱ⁺¹⁾ are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BLₙ₊₁). Therefore, the source line SLₙ and the bit line BLₙ are coupled to the nth column of AND memory cells 20 in the AND memory array A⁽ⁱ⁾ of the block BLOCK⁽ⁱ⁾, and are coupled to the nth column of AND memory cells 20 in the AND memory array A⁽ⁱ⁺¹⁾ of the block BLOCK⁽ⁱ⁺¹⁾. Similarly, the source line SLₙ₊₁ and the bit line BLₙ₊₁ are coupled to the (n+1)th column of AND memory cells 20 in the AND memory array A⁽ⁱ⁾ of the block BLOCK⁽ⁱ⁾, and are coupled to the (n+1)th column of AND memory cells 20 in the AND memory array A⁽ⁱ⁺¹⁾ of the block BLOCK⁽ⁱ⁺¹⁾.

Referring to FIG. 1B to FIG. 1D, the memory array 10 may be disposed on the interconnect structure of the semiconductor die. For example, the memory array 10 is disposed above one or more active devices (such as transistors) formed on the semiconductor substrate. Therefore, the dielectric substrate (or referred to as the dielectric layer) 50 is, for example, a dielectric layer formed above the metal interconnect structure on the silicon substrate, such as a silicon oxide layer. The memory array 10 may include a stacked structure 52 and a plurality of channel pillars VC.

Referring to FIG. 1B, the stacked structure 52 is formed on a dielectric substrate 50. The stacked structure 52 includes a plurality of gate layers (also referred to as word lines or conductive layers) 38 and a plurality of insulating layers 54 vertically stacked on the surface 50s of the dielectric substrate 50. In the third direction Z, these gate layers 38 are electrically isolated from each other by the insulating layers 54 arranged between them. The gate layer 38 extends in a direction parallel to the surface 50s of the dielectric substrate 50. The gate layers 38 of the staircase area (not shown) may have a staircase structure (not shown). Therefore, the gate layer 38 of the lower part is longer than the gate layer 38 of the upper part, and the end of the gate layer 38 of the lower part extends laterally and protrudes from the end of the gate layer 38 of the upper part. Contacts (not shown) for connecting the gate layers 38 may land at the ends of the gate layers 38, thereby connecting each gate layer 38 to each conductive line.

Referring to FIG. 1B to FIG. 1D, the memory array 10 further includes a plurality of channel pillars VC, and a channel pillar VC includes a channel layer 16 extending through the stacked structure 52. In some embodiments, the channel layer 16 may have a ring-shaped profile from the top view. The material of the channel layer 16 may be semiconductor, such as undoped polysilicon.

Referring to FIG. 1B to FIG. 1D, the channel pillar VC further includes an isolating pillar 28, a first conductive pillar 32a and a second conductive pillar 32b. In this example, the first conductive pillar 32a serves as the source pillar; the second conductive pillar 32b serves as the drain pillar. The first conductive pillar 32a, the second conductive pillar 32b and the isolating pillar 28 each extend in a direction (i.e., third direction Z) perpendicular to the surface (i.e., XY plane) of the gate layer 38. The first conductive pillar 32a and the second conductive pillar 32b are separated by the isolating pillar 28 and surrounded by the insulating filling layer 24. The first conductive pillar 32a and the second conductive pillar 32b are electrically connected to the channel layer 16. The first conductive pillar 32a and the second conductive pillar 32b include doped polysilicon or metal materials. The isolating pillar 28 is, for example, silicon nitride or silicon oxide, and the insulating filling layer 24 is, for example, silicon oxide.

Referring to FIG. 1C and FIG. 1D, the charge storage structure 40 is disposed between the channel layer 16 and the plurality of gate layers (or referred to as conductive layers) 38. The charge storage structure 40 may include a tunneling layer (or referred to as an energy gap engineered tunneling oxide layer) 14, a charge storage layer 12 and a blocking layer 36. The charge storage layer 12 is located between the tunneling layer 14 and the blocking layer 36. In some embodiments, the tunneling layer 14 and the blocking layer 36 include silicon oxide. The charge storage layer 12 includes silicon nitride, or other materials that can trap charges. In some embodiments, as shown in FIG. 1C, a portion of the charge storage structure 40 (tunneling layer 14 and charge storage layer 12) extends continuously in a direction (i.e., third direction Z) perpendicular to the gate layer 38, while another portion of the charge storage structure 40 (blocking layer 36) surrounds the gate layer 38. In other embodiments, as shown in FIG. 1D, the charge storage structure 40 (tunneling layer 14, charge storage layer 12 and blocking layer 36) surrounds the gate layer 38.

Referring to FIG. 1E, the charge storage structure 40, the channel layer 16, the source pillar 32a and the drain pillar 32b are surrounded by the gate layer 38 and define the memory cell 20. The memory cell 20 can perform 1-bit operation or 2-bit operation through different operation methods. For example, when a voltage is applied to the source pillar 32a and the drain pillar 32b, since the source pillar 32a and the drain pillar 32b are connected to the channel layer 16, electrons are transmitted along the channel layer 16 and stored in the entire charge storage structure 40, such that 1-bit operation is performed on the memory cell 20. In addition, for the operation using Fowler-Nordheim tunneling, electrons or holes are trapped in the charge storage structure 40 between the source pillar 32a and the drain pillar 32b. For the operation of source side injection, channel-hot-electron injection, or band-to-band tunneling hot carrier injection, electrons or holes are partially trapped in the charge storage structure 40 of one of the source pillar 32a and the drain pillar 32b adjacent to each other, so that the memory cell 20 is performed the operation of unit cell (SLC, 1 bit) or multi-level cell (MLC, greater than or equal to 2 bits).

In operation, when a voltage (for example, a corresponding starting voltage (Vth) higher than that of the corresponding memory cell 20) is applied to a selected word line (gate layer) 38, a channel region of the channel layer 16 intersecting the selected word line 38 is turned on, current is allowed to enter the drain pillar 32b from the bit line BLn or BLn+1 (shown in FIG. 1B) and flow to the source pillar 32a through the channel region being turned on (e.g., in the direction indicated by arrow 60), and finally flows to the source line SLn or SLn+1 (shown in FIG. 1B).

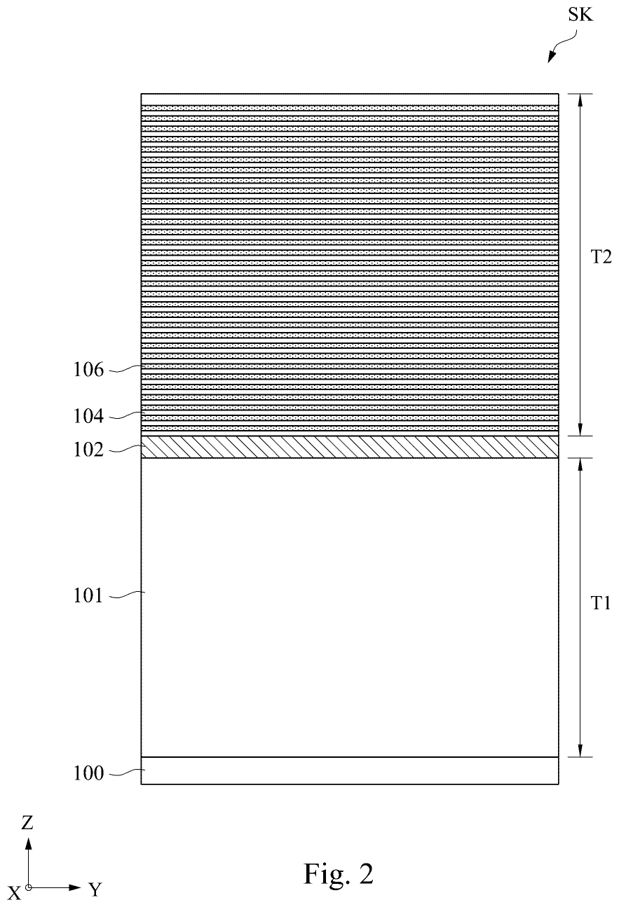

FIG. 2 to FIG. 14 are cross-sectional views of forming a 3D AND flash memory device in some embodiments of the present disclosure.

Referring to FIG. 2, a substrate 100, a buffer layer 101, and a conductive layer 102 are provided. The substrate 100 is, for example, a silicon substrate. The buffer layer 101 is, for example, a silicon oxide layer. The material of the conductive layer 102 is, for example, a grounded polysilicon layer. The conductive layer 102 can also be called a dummy gate, which can be used to close a leakage path. The substrate 100 includes an array region and a staircase region. A stacked structure SK is formed on the array region and the staircase region of the substrate 100 and the conductive layer 102, and the stacked structure SK is patterned to form a staircase structure in the staircase region. The stacked structure SK may also be referred to as an insulating stacked structure SK. In this embodiment, the stacked structure SK is composed of insulating layers 104 and intermediate layers 106 stacked sequentially and alternately on the conductive layer 102. In addition, in this embodiment, the uppermost layer of the stacked structure SK is the insulating layer 104. The insulating layer 104 is, for example, a silicon oxide layer. The intermediate layer 106 is, for example, a silicon nitride layer. The intermediate layers 106 are partially removed in the subsequent processes. The numbers of the insulating layers 104 and intermediate layers 106 may be formed according to actual needs.

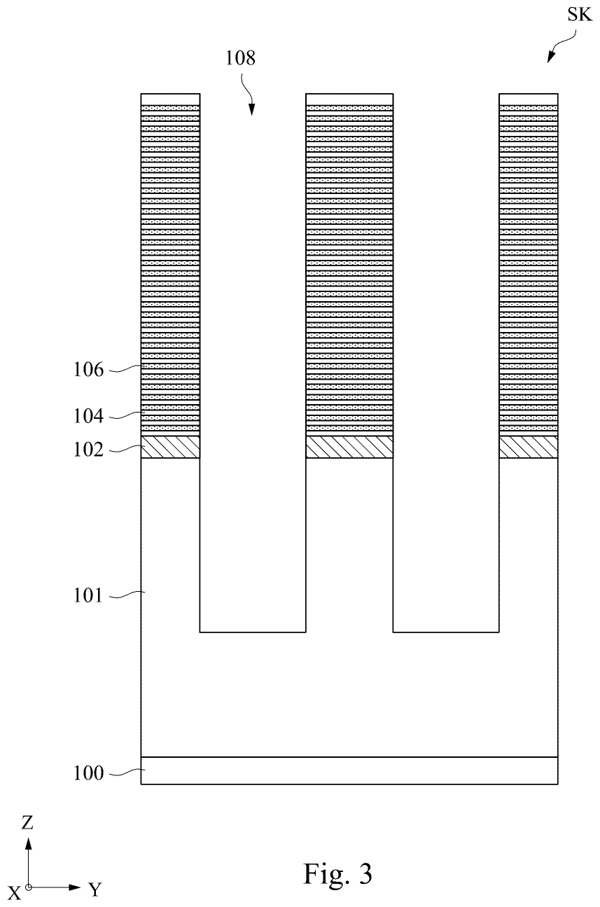

The thickness of the buffer layer 101 is designed, so that a width of a trench along a vertical direction formed in the stacked structure SK in subsequent processes is consistent enough. Accordingly, open issue between a source pillar (or a drain pillar) and a channel layer is avoided. In some embodiments, a thickness T1 of the buffer layer 101 ranges from is at least 30% of a thickness T2 of the stacked structure SK. In some embodiments, the thickness T1 of buffer layer 101 does not exceed 300% of the thickness T2 of the stacked structure SK. If the thickness T1 of the buffer layer 101 is less than the thickness T1 disclosed above, the channel trench (such as channel trench 108 in FIG. 3) formed in the subsequent process may totally penetrate the buffer layer 101. The substrate 100 below may be damaged accordingly. If the thickness T1 of the buffer layer 101 is greater than the thickness T1 disclosed above, it may easily cause substrate 100 warping, leading to uneven thickness of the deposited layer above the substrate 100 and the buffer layer 101.

Subsequently, referring to FIG. 3, a plurality of channel trenches 108 are formed in the array region of the stacked structure SK. The channel trenches 108 extend through the stacked structure SK and the conductive layer 102, and into the buffer layer 101. In this embodiment, from the top view, the channel trench 108 has a circular shape, but the disclosure is not limited thereto. In other embodiments, the channel trenches 108 may have other shapes, such as an oval or a polygon (not shown).

In the present disclosure, the channel trenches 108 are formed in the stacked structure SK by an etching process having high power and low selectivity. The etching process is a dry etching process performed under high power to the stacked structure SK, the conductive layer 102, and the buffer layer 101, so that the selectivity of the etching process to the intermediate layers 106 and the insulating layers 104, the conductive layer 102 and the buffer layer 101 is low. Therefore, the channel trenches 108 extend through the stacked structure SK and the conductive layer 102, and the channel trenches 108 expose the buffer layer 101. The channel trench 108 formed by the etching process mentioned above has a sidewall substantially perpendicular to the bottom surface of the buffer layer 101. The width of the channel trench 108 is consistent from bottom to top. In some embodiments, a thickness T1 of the buffer layer 101 ranges from is at least 30% of a thickness T2 of the stacked structure SK. In some embodiments, the thickness T1 of buffer layer 101 does not exceed 300% of the thickness T2 of the stacked structure SK. If the thickness T1 of the buffer layer 101 is less than the thickness T1 disclosed above, the channel trench 108 may totally penetrate the buffer layer 101. The substrate 100 below may be damaged accordingly. If the thickness T1 of the buffer layer 101 is greater than the thickness T1 disclosed above, it may easily cause substrate 100 warping, leading to uneven thickness of the deposited layer above the substrate 100 and the buffer layer 101. In some embodiments, the power of the etching process mentioned above ranges from 20 KHz to 400 KHz.

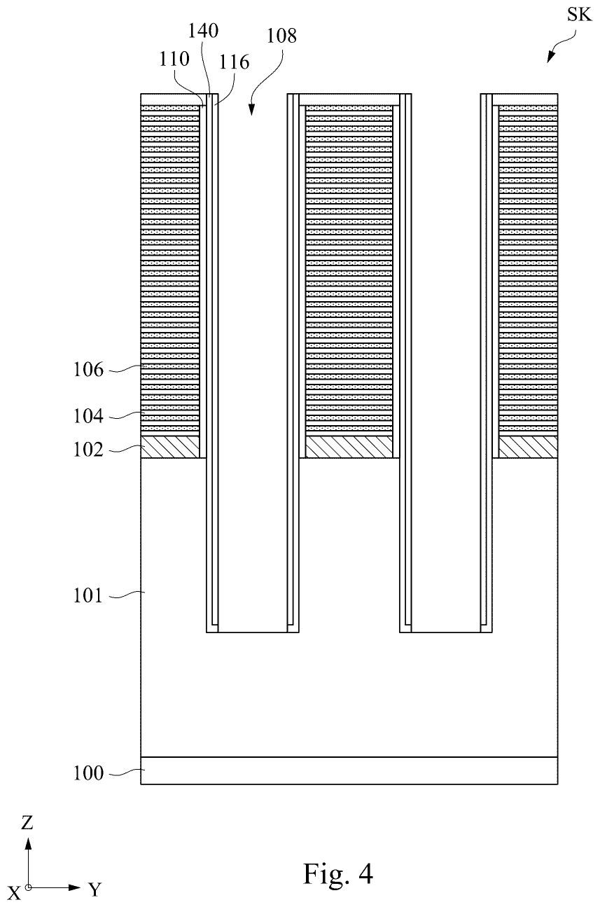

Referring to FIG. 4, a protection layer 110, a charge storage structure 140, and a channel layer 116 are formed lining the sidewall of each of the channel trench 108. The protection layer 110 is, for example, silicon oxide. The charge storage structure 140 may include a tunneling layer (such as the tunneling layer 14 shown in FIG. 1C), a charge storage layer (such as the charge storage layer 112 shown in FIG. 1C), and a blocking layer (such as the blocking layer 136 shown in FIG. 1C). The tunneling layer is, for example, silicon oxide. The storage layer is, for example, silicon nitride. The blocking layer is, for example, silicon oxide, a material with a high dielectric constant greater than or equal to 7, or a combination thereof. The material with a high dielectric constant greater than or equal to 7 includes aluminum oxide (Al₂O₃), hafnium oxide (HfO₂), lanthanum oxide (La₂O₅), transition metal oxide, lanthanide oxide or a combination thereof. The material of the channel layer 116 may be semiconductor material, such as un-doped polysilicon. The forming method of the protection layer 110 is, for example, a thermal oxidation process, a chemical vapor deposition, or an atomic layer deposition. The method of forming the charge storage structure 140 and the channel layer 116 is, for example, forming charge storage structure materials, a channel material and a spacer material on the stacked structure SK and in the channel trench 108. Next, an etching back process is performed to partially remove the charge storage structure materials, the channel material and the spacer material to form the charge storage structure 140, the channel layer 116 and the spacer (not shown). The protection layer 110, the charge storage structure 140, and the channel layer 116 cover the sidewall of the channel trench 108, and expose the bottom of the channel trench 108. The protection layer 110, the charge storage structure 140, and the channel layer 116 extend through the stacked structure SK and extend into the buffer layer 101. From the top view, the channel layer 116 is, for example, in ring shape. In some embodiments, the channel layer 116 may have a circular shape from the top view, but the disclosure is not limited thereto. In other embodiments, the channel layer 116 may also have other shapes (such as ovals or polygons) from the top view. The spacer will be removed in the subsequent processes.

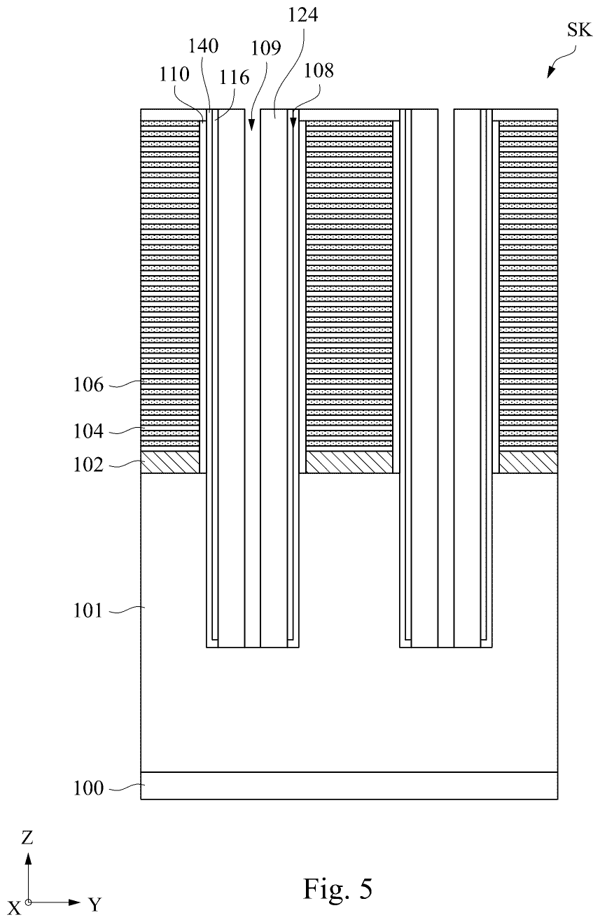

Referring to FIG. 5, an insulating filling layer is formed above the stacked structure SK and in the channel trenches 108. The material of the insulating filling layer is, for example, low-temperature silicon oxide or high-temperature silicon oxide. The insulating filling material filled in the channel trench 108 forms an insulating filling layer 124, and a circular void is left at the center of the insulating filling layer 124. Then, an anisotropic etching process is performed to enlarge the circular void to form a hole 109. In this embodiment, the hole 109 extends through the conductive layer 102, and the bottom surface of the hole 109 is between the top surface and the bottom surface of the buffer layer 101.

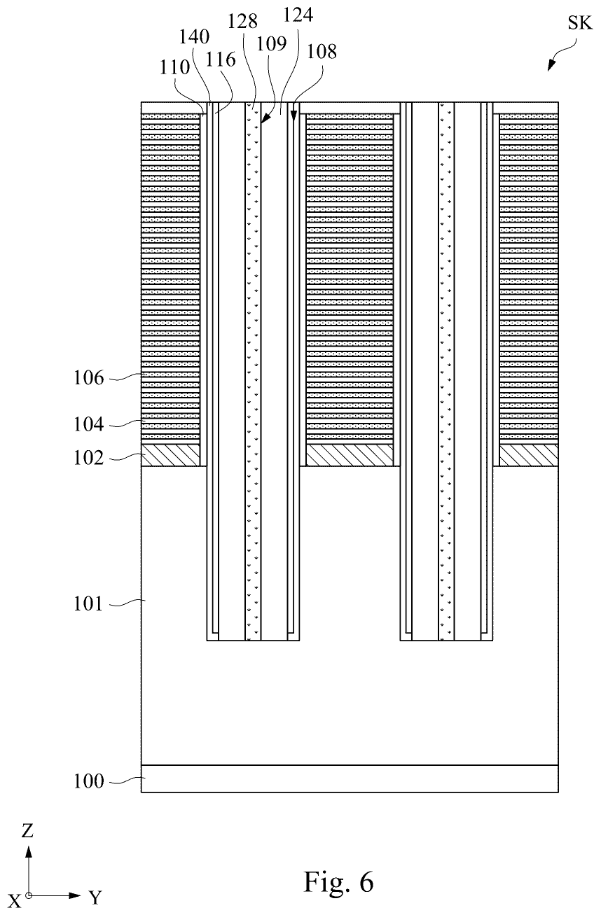

Referring to FIG. 6, an insulating material is formed on the insulating filling layer 124 and filled in the hole 109. Then, an anisotropic etching process is performed to remove a part of the insulating material to form an isolating pillar 128 in the hole 109. The isolating pillar 128 is formed within the channel layer 116. The material of the isolating pillar 128 is different from the material of the insulating filling layer 124. The material of the isolating pillar 28 is, for example, silicon nitride.

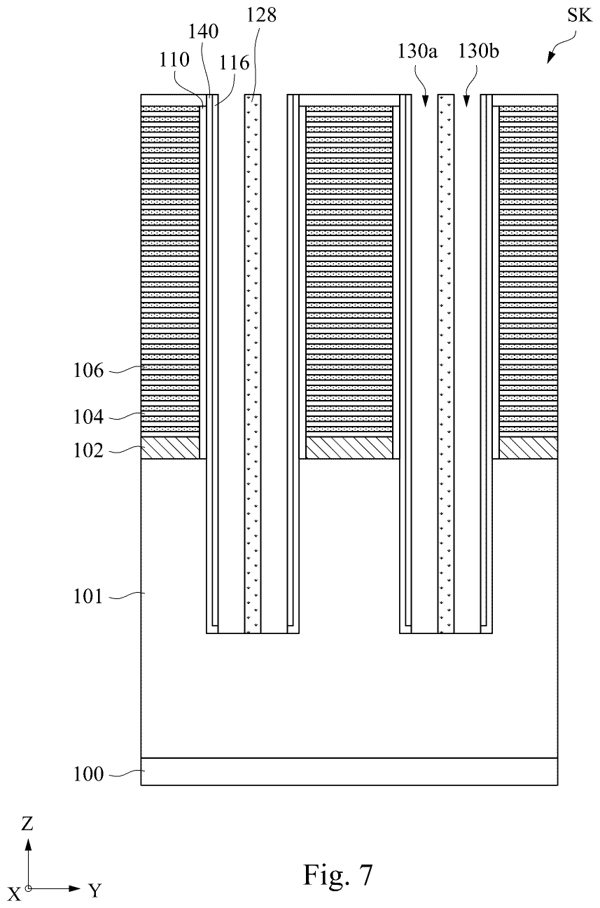

Referring to FIG. 7, a patterning processes is performed to form holes 130a and 130b in the insulating filling layer 124. The profiles of the holes 130a and 130b may be tangent to the profile of the isolating pillar 128. The profiles of the holes 130a and 130b may also exceed the profile of the isolating pillar 128. The profiles of the holes 130a and 130b may be tangent to the profile of the channel layer 116. The profiles of the holes 130a and 130b may also exceed the profile of the channel layer 116. That is, the sidewalls of the holes 130a and 130b expose a portion of the isolating pillar 128 and the channel layer 116. In the present disclosure, the holes 130a and 130b are formed in the insulating filling layer 124 by a dry etching process having high power and low selectivity. The holes 130a and 130b formed by the etching process mentioned above have sidewalls substantially perpendicular to the bottom surface of the buffer layer 101. The widths of the holes 130a and 130b are consistent from bottom to top. That is, the sidewalls of the holes 130a and 130b expose the isolating pillar 128 and the channel layer 116 from bottom to top. In some embodiments, the power of the etching process mentioned above ranges from 20 KHz to 400 KHz.

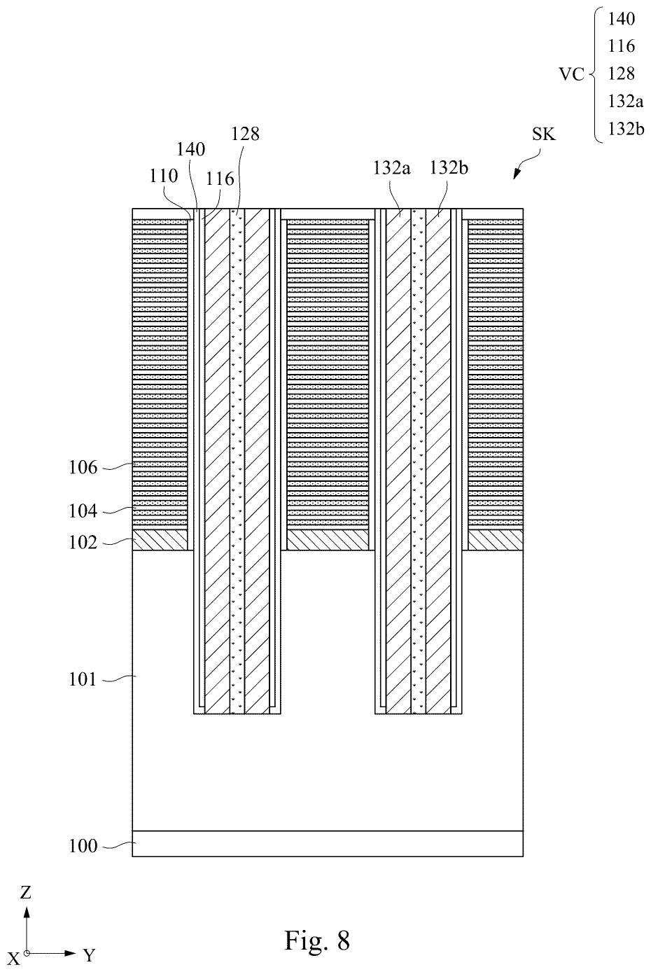

Referring to FIG. 8, a conductive pillar 132a and a conductive pillar 132b are formed in the hole 130a and the hole 130b. The conductive pillar 132a and the conductive pillar 132b may be used as a source pillar and a drain pillar respectively. The conductive pillar 132a and the conductive pillar 132b are formed within the channel layer 116 and electrically connected to the channel layer 116 respectively. The conductive pillar 132a and the conductive pillar 132b are separated by the isolating pillar 128. The conductive pillar 132a and the conductive pillar 132b may be formed by forming a conductive layer on the insulating filling layer 124 and in the holes 130a and 130b, and then etching back the conductive layer. The conductive pillar 132a and the conductive pillar 132b are, for example, doped polysilicon. As a result, channel pillars VC are formed in the channel trenches 108 (see FIG. 6). The channel pillars VC extend through the stacked structure SK and are embedded in the buffer layer 101. The channel pillar VC includes the charge storage structure 140, the channel layer 116, the isolating pillar 128, the conductive pillar 132a and the conductive pillar 132b.

In the present disclosure, the widths of the holes 130a and 130b are consistent from bottom to top. Therefore, the sidewalls of the holes 130a and 130b expose the isolating pillar 128 and the channel layer 116 from bottom to top. As a result, the conductive pillar 132a and the conductive pillar 132b formed in the holes 130a and 130b are in contact with the channel layer 116 from bottom to top. That is, the widths of the conductive pillar 132a and the conductive pillar 132b are consistent from bottom to top. Therefore, even the sidewalls of the bottom ends of the conductive pillar 132a and the conductive pillar 132b are in contact with the channel layer 116, and the sidewall of the bottom end of the charge storage structure 140 is in contact with the conductive pillar 132a and the conductive pillar 132b. The open issue between the conductive pillar 132a (or the conductive pillar 132b) and the channel layer 116 is reduced. In addition, the bottom end of the isolating pillar 128 is in contact with the conductive pillar 132a and the conductive pillar 132b.

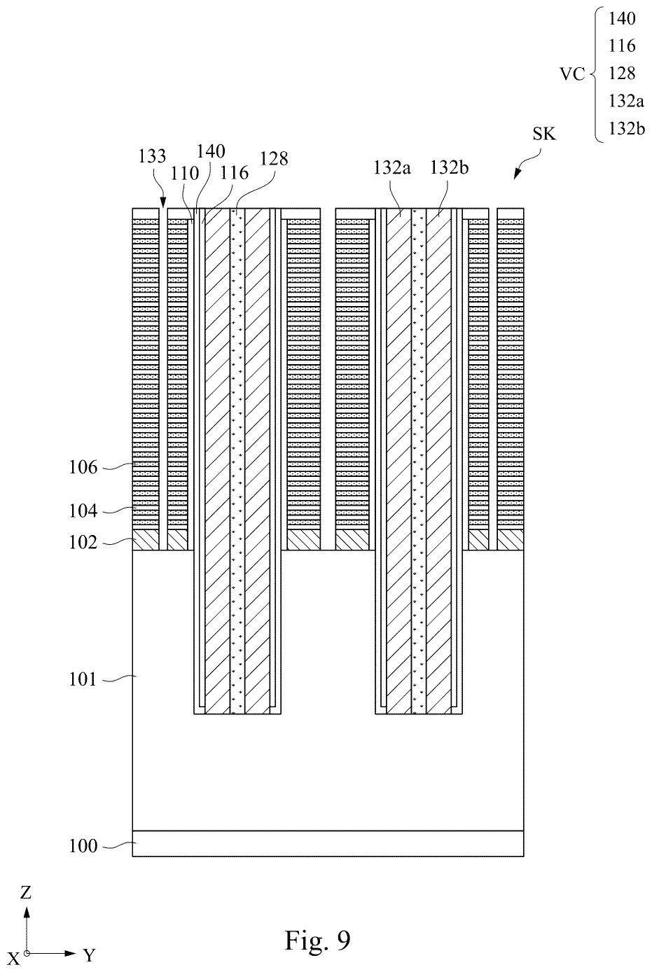

Referring to FIG. 9, a patterning process, such as lithography and etching processes, is performed to the stacked structure SK and the conductive layer 102 to form a plurality of slit trenches 133 extending through the stacked structure SK and the conductive layer 102. The bottom portion of the slit trenches 133 expose the buffer layer 101, and the bottom portion of the slit trenches 133 are higher than the bottom portion of the isolating pillar 128. In some embodiments, the slit trenches 133 extend in a first direction (such as X direction shown in FIG. 9).

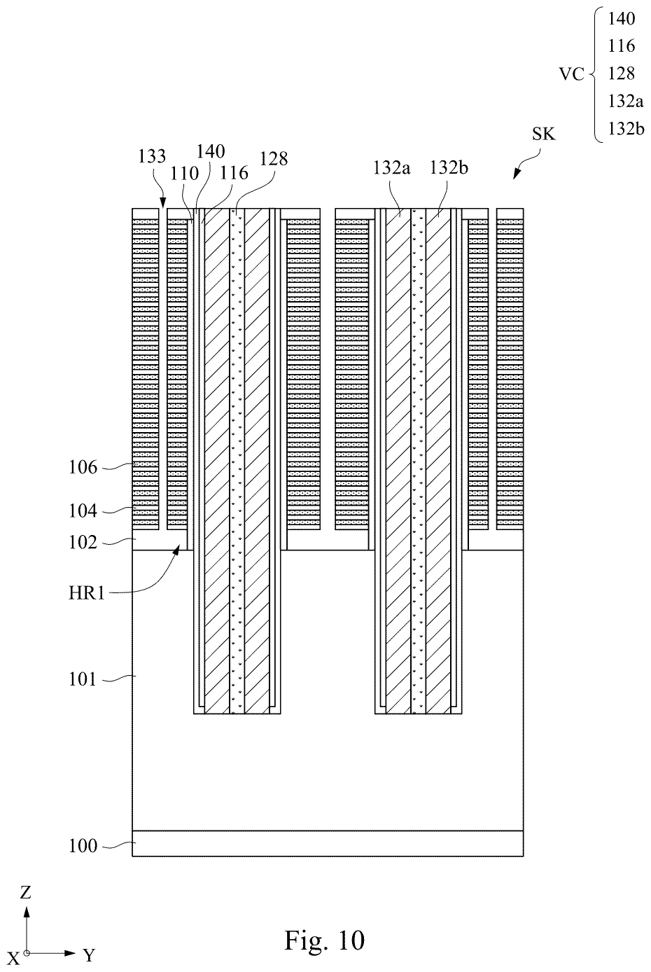

Referring to FIG. 10, an etching process, such as a wet etching process, is performed to laterally remove the conductive layer 102. An etchant for the wet etching process is selected to remove the conductive layer 102 while other material layers are substantially intact. Therefore, after the conductive layer 102 is removed, horizontal recesses HR1 are formed between the stacked structure SK and the buffer layer 101, and the sidewall of the protection layer 110 layer is exposed. It is noted that although the conductive layer 102 is removed in FIG. 10, the conductive layer 102 remains at some portions of the entire flash memory device to maintain the function thereof. For example, the conductive layer 102 is only removed in the array region.

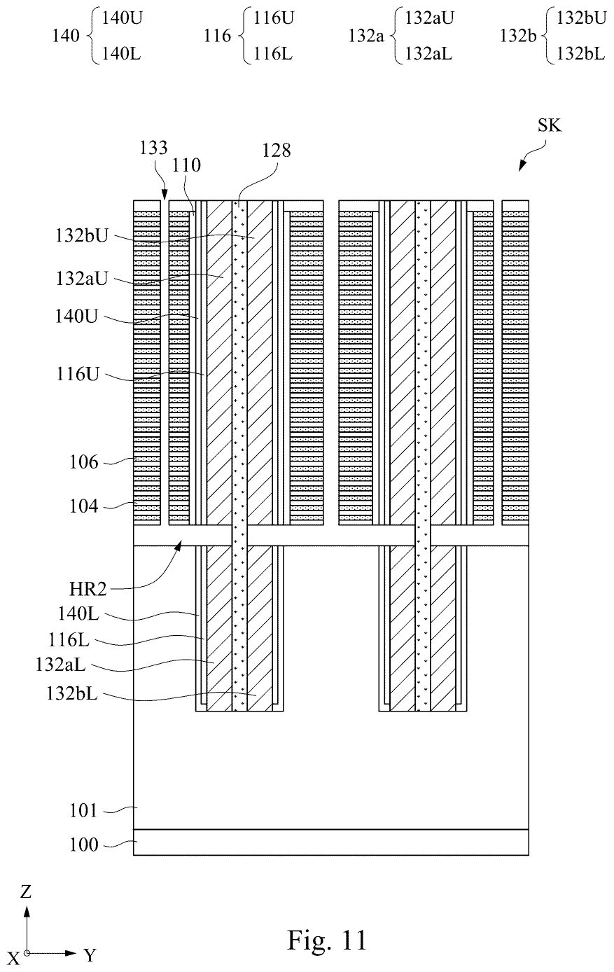

Referring to FIG. 11, an etching process is performed to laterally remove portions of the protection layer 110, the charge storage structure 140, the channel layer 116, the conductive pillar 132a, and the conductive pillar 132b from the horizontal recess HR1 to form a horizontal recess HR2 exposing a sidewall of the isolating pillar 128. In the present disclosure, the etching process used for removing the protection layer 110 and the charge storage structure 140 from the horizontal recess HR1 may be a dry etching process, and the parameters may be adjusted to remove the protection layer 110 and the charge storage structure 140 from the horizontal recess HR1 while the insulating layers 104 and the intermediate layers 106 of the stacked structure SK are substantially intact. The etching process used for removing the channel layer 116, the conductive pillar 132a, and the conductive pillar 132b from the horizontal recess HR1 may be a dry etching processor or a wet etching process.

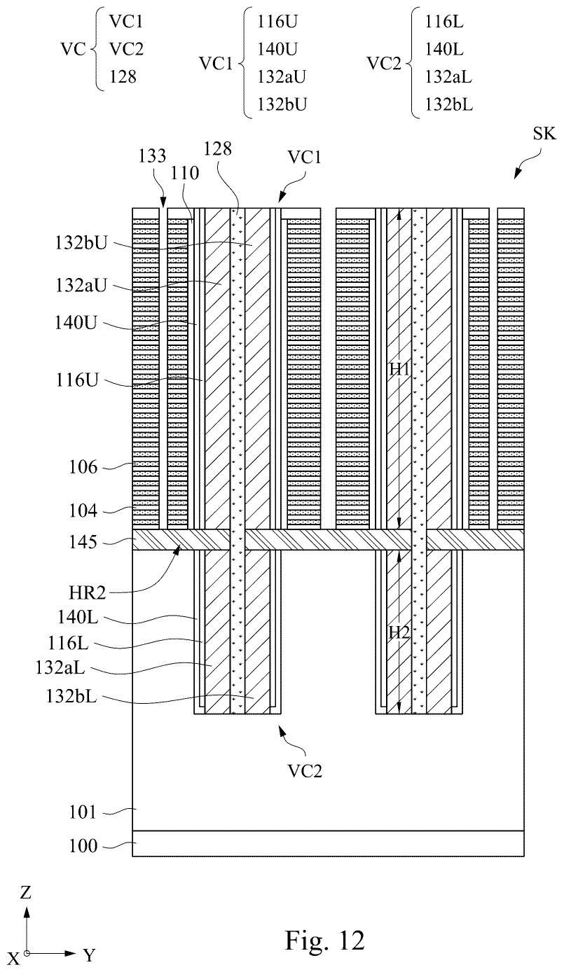

Referring to FIG. 12, an insulating layer 145 is formed in the horizontal recess HR2 and on the buffer layer 101, such that the insulating layer 145 is in contact with the sidewall of the isolating pillar 128. The insulating layer 145 is between the stacked structure SK and the buffer layer 101. That is, in FIG. 11 and FIG. 12, a portion of the conductive layer 102 and a portion of the channel pillar VC are replaced by the insulating layer 145. In some embodiments, the insulating layer 145 may be forming by thermal oxidation process, chemical vapor deposition or atomic layer deposition. In some embodiments, the insulating layer 145 is, for example, silicon oxide, and the insulating layer 145 and the isolating pillar 128 are made of different materials.

In the present disclosure, after forming the insulating layer 145, the channel pillar VC includes a memory pillar VC1 in the stacked structure SK and a support pillar VC2 in the buffer layer 101. The memory pillar VC1 and the support pillar VC2 are separated by the insulating layer 145. The isolating pillar 128 extends from the memory pillar VC1 to the support pillar VC1 and penetrates through the insulating layer 145. In the subsequent memory operation, the memory pillar VC1 will be used for the channel region of the memory device, and the support pillar VC2 will not participate in the memory operation. In some embodiments, a vertical height H2 of the support pillar VC2 ranges from 20% to 100% of a vertical height H1 of the memory pillar VC1.

Specifically, when the insulating layer 145 is formed, the insulating layer 145 penetrates the conductive pillar 132a and the conductive pillar 132b, such that the memory pillar VC1 in the stacked structure SK includes a conductive upper pillar 132aU of the conductive pillar 132a and a conductive upper pillar 132bU of the conductive pillar 132b. The isolating pillar 128 electrically isolates the conductive upper pillar 132aU and the conductive upper pillar 132bU. The support pillar VC2 includes a conductive lower pillar 132aL of the conductive pillar 132a and a conductive lower pillar 132bL of the conductive pillar 132b. The conductive lower pillar 132aL is below the conductive upper pillar 132aU, and the conductive lower pillar 132bL is below the conductive upper pillar 132bU. The insulating layer 145 separates the conductive lower pillar 132aL and the conductive upper pillar 132aU and separates the conductive lower pillar 132bL and the conductive upper pillar 132bU. Moreover, the insulating layer 145 also penetrates the charge storage structure 140a and the channel layer 116, such that the memory pillar VC1 includes the charge storage structure 140U and the channel layer 116U on the insulation layer 145, and the support pillar VC2 includes the charge storage structure 140L and the channel layer 116L under the insulation layer 145. It is noted that the charge storage structure 140L and the channel layer 116L of the support pillar VC2 do not have the function of storing charges or cannot serve as a channel. Therefore, the charge storage structure 140L may also be referred to as the dielectric structure 140L, and the channel layer 116L may also be referred to as the polysilicon layer 116L. The dielectric structure 140L and the charge storage structure 140U are separated by the insulating layer 145 and extend in a same axial direction. The polysilicon layer 116L and the channel layer 116U are separated by the insulating layer 145 and extend in a same axial direction. In the present disclosure, the widths of the conductive upper pillar 132aU and the conductive upper pillar 132bU are also consistent from bottom to top.

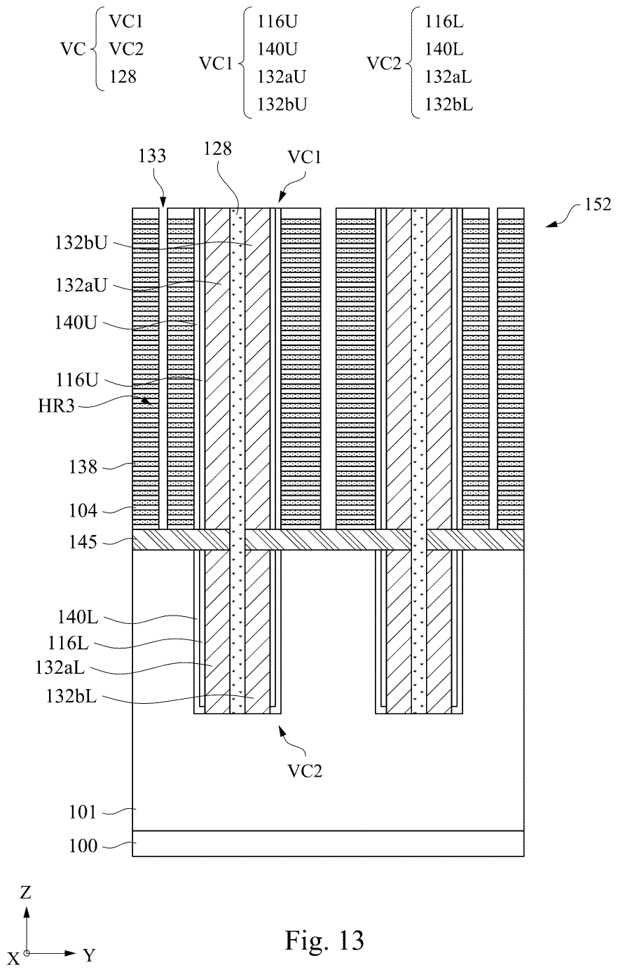

Referring to FIG. 13, a partial replacement process is performed on the intermediate layers 106. First, an etching process, such as a wet etching process, is performed to remove the intermediate layers 106 surrounding the slit trenches 133. An etching solution (e.g., hot phosphoric acid) used in the etching process is injected into the slit trench 133, and then the contacted portions of the intermediate layers 106 are removed. When the intermediate layers 106 between the channel layer 116 and the slit trench 133 are removed, since the material of the protection layer 110 is different from the material of the intermediate layers 106, the protection layer 110 may serve as etch stop layers to protect the channel layer 116. The etching process is continued, and through time mode control, most of the intermediate layers 106 are removed to form a plurality of horizontal recesses HR3. The protection layer 110 on the sidewalls of the intermediate layers 106 may be removed during the etching process. In some embodiments, a removal process may be performed to remove the plurality of residues from the formation of the insulating layer 145 remaining at the sidewall of the slit trench 133 before the plurality of intermediate layers 106 are removed. In some embodiments, the slit trench 133 is widened and deepened, and a portion of the dielectric layer is removed to expose the buffer layer 101.

Subsequently, gate layers (or conductive layers) 138 are formed in the horizontal recesses HR3, and the intermediate layers 106 are replaced by the gate layers 138. The material of the gate layer 138 is, for example, tungsten. In some embodiments, barrier layers are formed before the gate layers 138 are formed. The barrier layer is, for example, titanium (Ti), titanium nitride (TiN), tantalum (Ta), tantalum nitride (TaN), or a combination thereof. As a result, a gate stacked structure 152 is formed on the insulating layer 145, and the gate stacked structure 152 includes a plurality of the gate layers 138 and a plurality of insulating layers 104 stacked alternately.

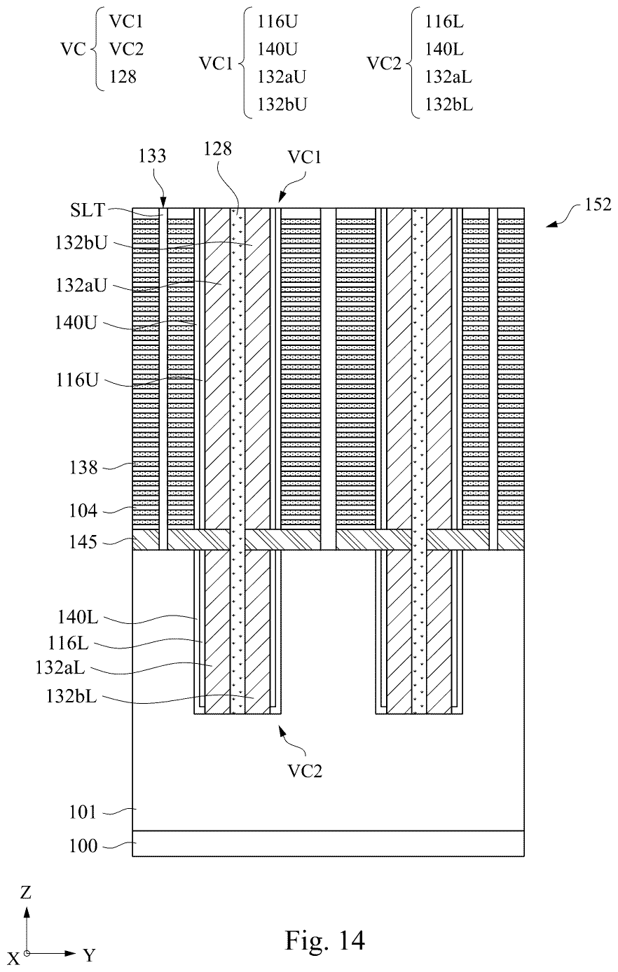

Referring to FIG. 14, a slit SLT is formed in the slit trench 133. The method of forming the slit SLT includes filling an insulating liner material and a conductive material on the gate stack structure 152 and in the slit trench 133. The insulating liner material is, for example, silicon oxide. The conductive material is, for example, polysilicon. Then, the excessive insulating liner material and conductive material on the gate stack structure 152 are removed by an etch-back process or a planarization process to form a liner layer 162 and a conductive layer 164. The liner layer 162 and the conductive layer 164 are collectively referred to as a slit SLT. In other embodiments, the slit SLT may also be completely filled with an insulating material without any conductive layer. In still other embodiments, the slit SLT may also be a liner layer 142, and the liner layer 142 covers an air gap without any conductive layer. The slit SLT extends through the gate stacked structure 152 and the insulating layer 145 in a first direction (such as X direction shown in FIG. 14), such that the slit SLT is in contact with the insulating layer 145 and the isolating pillar 128 of the channel pillar VC in a second direction (such as Y direction shown in FIG. 14).

Afterwards, a contact (not shown) is formed in the staircase region. The contact lands on the end of the gate layer 138 in the staircase region and is electrically connected thereto.

As mentioned above, the resulting flash memory device includes a substrate 100, a buffer layer 101, a gate stacked structure 152, and a channel pillar VC. The buffer layer 101 is on the substrate 100. The gate stacked structure 152 is located on the buffer layer 101, in which the gate stacked structure SK includes a plurality of gate layers 138 and a plurality of insulating layers 104 stacked alternately. The channel pillar VC extends through the gate stacked structure 152 and is embedded in the buffer layer 101, in which the channel pillar VC includes a charge storage structure 140U and a channel layer 116U, the charge storage structure 140U is located between the plurality of gate layers 138 and the channel layer 116U.

The channel pillar VC includes a memory pillar VC1 and a support pillar VC2. The memory pillar VC1 is in the gate stacked structure 152, and includes the charge storage structure 140U, the channel layer 116U, a conductive upper pillar 132aU and a conductive upper pillar 132bU. The support pillar VC2 is in the buffer layer 101, and includes a dielectric structure 140L, a polysilicon layer 116L, a conductive lower pillar 132aL and a conductive lower pillar 132bL. The conductive upper pillar 132aU and the conductive upper pillar 132bU are separated by an isolating pillar 128, and the memory pillar VC1 and the support pillar VC2 are separated by an insulating layer 145.

In the present disclosure, the conductive upper pillars 132aU and 132bU are formed by a dry etching process having high power and low selectivity, and have sidewalls substantially perpendicular to the bottom surface of the buffer layer 101. That is, the widths of the conductive upper pillars 132aU and 132bU are consistent from bottom to top. The sidewalls of the conductive upper pillars 132aU and 132bU are ensured to be in contact with the channel layer 116 to avoid the open issue between the conductive upper pillar 132aU (or the conductive upper pillar 132bU) and the channel layer 116 within the range of height of the gate stacked structure 152, especially near the bottom portion of the gate stacked structure 152. In order to prevent the channel pillar VC exceeding the range of height of the gate stacked structure 152 cause negative impact on the operation of the flash memory, the insulating layer 145 is used to divide the channel pillar VC into the memory pillar VC1 and the support pillar VC2. As a result, the support pillar VC2 in the buffer layer 101 is not electrically connected to the memory pillar VC1 and any of the gate layers 138, and thus will not cause interference during the operation of the memory device.

The above embodiments are described by taking an AND flash memory as an example. The present disclosure can also be applied in a three-dimensional NOR flash memory and a three-dimensional NAND flash memory.

What is claimed is:

1. A memory device comprising:
a substrate;
a buffer layer on the substrate;
a stacked structure located on the buffer layer, wherein the stacked structure comprises a plurality of gate layers and a plurality of first insulating layers stacked alternately; and
a channel pillar extending through the stacked structure and embedded in the buffer layer, wherein the channel pillar comprises a charge storage structure and a channel layer, the charge storage structure located between the plurality of gate layers and the channel pillar.

2. The memory device of claim 1, further comprising a second insulating layer between the stacked structure and the buffer layer, the channel pillar comprising a memory pillar in the stacked structure and a support pillar in the buffer layer, wherein the memory pillar and the support pillar are separated by the second insulating layer.

3. The memory device of claim 2, wherein the channel pillar comprises an isolating pillar, the isolating pillar extends from the memory pillar to the support pillar and penetrates through the second insulating layer.

4. The memory device of claim 3, wherein the memory pillar comprises a first conductive upper pillar and a second conductive upper pillar, wherein the first conductive upper pillar and the second conductive upper pillar are electrically separated by the isolating pillar.

5. The memory device of claim 4, wherein the support pillar comprises a first conductive lower pillar below the first conductive upper pillar and a second conductive lower pillar below the second conductive upper pillar, wherein the second insulating layer separates the first conductive lower pillar and the first conductive upper pillar and separates the second conductive lower pillar and the second conductive upper pillar.

6. The memory device of claim 3, wherein the second insulating layer and the isolating pillar are made of different materials.

7. The memory device of claim 2, wherein the support pillar comprises a dielectric structure and a polysilicon layer, the dielectric structure and the charge storage structure are separated by the second insulating layer and extend in a same axial direction, the polysilicon layer and the channel layer are separated by the second insulating layer and extend in a same axial direction.

8. The memory device of claim 2, wherein a vertical height of the support pillar ranges from 20% to 100% of a vertical height of the memory pillar.

9. The memory device of claim 2, further comprising:
a slit extending through the stacked structure and the second insulating layer in a first direction, such that the second insulating layer is in contact with the slit and the channel pillar in a second direction.

10. The memory device of claim 1, wherein a thickness of the buffer layer is at least greater than 30% of a thickness of the stacked structure.

11. A manufacturing method of a memory device comprising:
forming a conductive layer on a buffer layer on a substrate;
forming a stacked structure on the conductive layer, wherein the stacked structure comprises a plurality of intermediate layers and a plurality of first insulating layers stacked alternately;
forming a channel trench extending through the stacked structure and the conductive layer into the buffer layer;
forming a channel pillar in the channel trench;
forming a slit trench extending through the stacked structure and the conductive layer;
replacing the conductive layer and a portion of the channel pillar by a second insulating layer;
replacing the plurality of intermediate layers by a plurality of gate layers; and
forming a slit in the slit trench.

12. The manufacturing method of claim 11, wherein forming the channel pillar comprises:
forming a charge storage structure lining a sidewall of the channel trench;
forming a channel layer lining the charge storage structure;
forming an isolating pillar within the channel layer; and
forming a first conductive pillar and a second conductive pillar separated by the isolating pillar.

13. The manufacturing method of claim 12, wherein after replacing the conductive layer and the portion of the channel pillar by the second insulating layer, a memory pillar of the channel pillar is formed in the stacked structure, and a support pillar of the channel pillar is formed in the buffer layer, and the memory pillar and the support pillar is separated by the second insulating layer.

14. The manufacturing method of claim 13, wherein the second insulating layer penetrates the first conductive pillar and the second conductive pillar, such that the memory pillar comprises a first conductive upper pillar of the first conductive pillar and a second conductive upper pillar of the second conductive pillar, and the support pillar comprises a first conductive lower pillar of the first conductive pillar and a second conductive lower pillar of the second conductive pillar.

15. The manufacturing method of claim 14, wherein the memory pillar comprises the charge storage structure and the channel layer on the second insulation layer after replacing the conductive layer and the portion of the channel pillar by the second insulating layer.

16. The manufacturing method of claim 13, wherein after replacing the conductive layer and the portion of the channel pillar by the second insulating layer, the isolating pillar extends from the memory pillar to the support pillar.

17. The manufacturing method of claim 12, wherein a bottom surface of the slit trench is higher than a bottom surface of the isolating pillar.

18. The manufacturing method of claim 17, wherein the second insulating layer is in contact with the isolating pillar and the slit.

19. The manufacturing method of claim 11, wherein the slit penetrates through the second insulating layer.

20. The manufacturing method of claim 11, wherein a thickness of the buffer layer is at least greater than 30% of a thickness of the stacked structure.
